(19) United States
(12) Patent Application Publication
(10) Pub. No.: US 2024/0250213 A1
(43) Pub. Date: Jul. 25, 2024

(54) METHOD OF MANUFACTURING III-NITRIDE SEMICONDUCTOR LIGHT EMITTING STRUCTURE

(71) Applicant: Soft-Epi Inc., Gyeonggi-do (KR)

(72) Inventors: Sung Min HWANG, Gyeonggi-do (KR); Hyung Kyu CHOI, Gyeonggi-do (KR); Doo Soo KIM, Gyeonggi-do (KR); Sung Woon HEO, Gyeonggi-do (KR); Sung Ju MUN, Gyeonggi-do (KR); In Seong CHO, Gyeonggi-do (KR); Won Taeg LIM, Gyeonggi-do (KR)

(21) Appl. No.: 18/290,056

(22) PCT Filed: May 11, 2022
(86) PCT No.: PCT/KR2022/006780

§ 371 Date: Nov. 9, 2023

(30) Foreign Application Priority Data
May 11, 2021 (KR) 10-2021-0060792
Jun. 4, 2021 (KR) 10-2021-0072818

(51) Int. Cl. H01L 33/32; H01L 33/00; H01L 33/06

(52) U.S. Cl. CPC H01L 33/325; H01L 33/007; H01L 33/06

(57) ABSTRACT

This disclosure generally relates to a method for manufacturing a Group III-nitride semiconductor light emitting structure. In particular, it relates to a method for manufacturing a Group III-nitride semiconductor light emitting structure capable of shifting the emission wavelength towards to a longer wavelength through an appropriate barrier (the Group III-nitride semiconductor is composed of a compound of Al(x)Ga(y)In(1-x-y)N (0≤x≤1, 0≤y≤1, 0≤x+y≤1)).

### FIELD

This disclosure generally relates to a method for manufacturing a Group III-nitride semiconductor light emitting structure. In particular, it relates to a method for manufacturing a Group III-nitride semiconductor light emitting structure capable of shifting the emission wavelength towards to a longer wavelength through an appropriate barrier. Here, the Group III-nitride semiconductor is composed of a compound of Al(x)Ga(y)In(1-x-y)N (0≤x≤1, 0≤y≤1, 0≤x+y≤1).

### BACKGROUND

This section provides background information related to the present disclosure which is not necessarily

Up to date, commercially available semiconductor light emitting devices (e.g. LED, LD) that emit light in the red color range are made of AlGaInP-based compound semiconductors, but recently those emitting light in yellow, amber, orange, red, and infrared ranges have been considered.

FIG. 1 shows an example of a conventional Group III nitride semiconductor light emitting device that emits light in a red color range. The semiconductor light emitting device includes a growth substrate 10 (e.g., a patterned C-plane sapphire substrate (PSS)), a buffer region 20 (e.g., un-doped GaN (2 μm) formed on a seed layer (GaN grown at a low temperature), an n-side contact region 30 (e.g., Si-doped GaN (2-8 μm) and Si-doped Al_{0.03}Ga_{0.97}N (1 μm)), a superlattice region 31 (e.g., 15 cycle GaN (6 nm)/In_{0.08}Ga_{0.92}N (2 nm)), 15 nm-thick Si-doped GaN 32, an In-deplete quantum well structure 41 (e.g., a quantum well made of In_{0.2}Ga_{0.8}N (2 nm) and a barrier made of GaN (2 nm)/Al_{0.13}Ga_{0.87}N (18 nm)/GaN (3 nm)), a red light emitting active region 42 (e.g., a quantum well made of InGaN (2.5 nm)-a barrier made of AlN (1.2 nm)/GaN (2 nm)/Al_{0.13}Ga_{0.87}N (18 nm)/GaN (3 nm))-quantum well made of InGaN (2.5 nm)-a barrier made of AlN (1.2 nm)/GaN (23 nm)), a 15 nm thick GaN layer 43, a p-side region 50 (e.g., Mg-doped GaN (100 nm) and p+-GaN:Mg (10 nm)), a current spreading electrode 60 (e.g., ITO), a first electrode 70 (e.g., Cr/Ni/Au), and a second electrode 80 (e.g., Cr/Ni/Au) (Article titled “633-nm InGaN-based red LEDs grown on thick underlying GaN layers with reduced in-plane residual stress”, Applied Physics Letters, April 2020).

In addition, U.S. Pat. No. 10,396,240 also discloses a semiconductor light emitting device that emits light in a red range using an InGaN active region.

### SUMMARY

This section provides a general summary of the disclosure and is not a comprehensive disclosure of its full scope or all of its features.

One aspect of the present disclosure provides a method for manufacturing a Group III nitride semiconductor light emitting structure that emits red light having an emission peak wavelength of at least 600 nm, the method comprising: growing a first superlattice region formed of alternating stacked first sub-layers and second sub-layers; and growing an active region on the first superlattice region, with the active region including a third sub-layer made of an Al-containing Group III nitride semiconductor and having a first bandgap energy, a fourth sub-layer made of an In-containing Group III nitride semiconductor and having a second bandgap energy smaller than the first bandgap energy and a fifth sub-layer made of an Al-containing Group III nitride semiconductor and having a third bandgap energy smaller than the second bandgap energy, wherein if the third sub-layer and the fifth sub-layer is based on GaN, the In content in the fourth sub-layer is set such that the fourth sub-layer emits light having a peak emission wavelength of 600 nm or less, and wherein the Al content in the third sub-layer and the Al content in the fifth sub-layer are set such that the fourth sub-layer emits red light having a peak emission wavelength of at least 600 nm.

A person of ordinary skill in the art will understand, that any method described above or below and/or claimed and described as a sequence of steps is not restrictive in the sense of the order of steps.

### BRIEF DESCRIPTION OF THE DRAWINGS

Various objects, features and attendant advantages of the present invention will become fully appreciated when considered in conjunction with the accompanying drawings, in which like reference characters designate the same or similar parts throughout the several views, and wherein:

FIG. 1 shows an example of a conventional Group III nitride semiconductor light emitting device that emits light in a red range;

FIG. 2 shows an example of a Group III nitride semiconductor light emitting device according to the present disclosure;

FIG. 3 shows examples of a semiconductor light emitting structure according to the present disclosure;

FIG. 4 shows other examples of a semiconductor light emitting structure according to the present disclosure;

FIG. 5 shows another example of a semiconductor light emitting structure according to the present disclosure;

FIG. 6 shows an example of experiment results in the present disclosure;

FIG. 7 shows another example of experimental results in the present disclosure;

FIG. 8 shows another example of experimental results in the present disclosure;

FIG. 9 shows another example of experimental results in the present disclosure;

FIG. 10 shows another example of experimental results in the present disclosure;

FIG. 11 illustrates bandgap energy of different semiconductor light emitting devices;

FIGS. 12, 13 and 14 show further examples of experimental results in the present disclosure;

FIG. 15 compares an active regions of the quantum well structure with an active region of the superlattice structure;

FIG. 16 shows an example of experimental results in the semiconductor light emitting structure described in Table 7;

FIG. 17 illustrates various examples of semiconductor light emitting structures employing a superlattice structure.

### DETAILED DESCRIPTION OF THE PREFERRED EMBODIMENTS

Hereinafter, the present disclosure will now be described in detail with reference to the accompanying drawing(s).

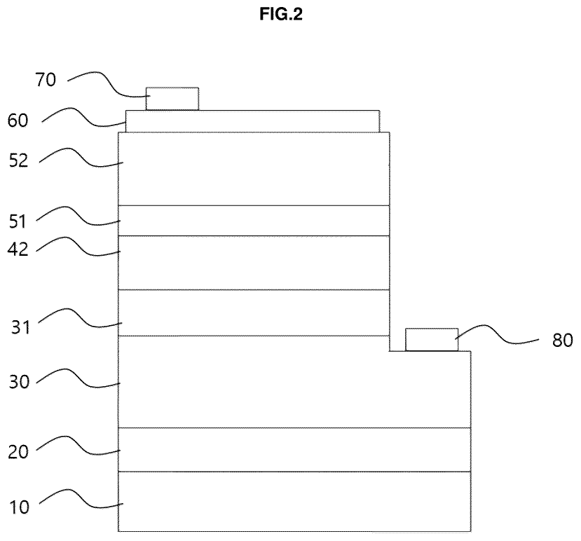

FIG. 2 shows an example of a Group III nitride semiconductor light emitting device according to the present disclosure, in which the semiconductor light emitting device includes a growth substrate 10, a buffer region 20, an n-side contact region 30, a superlattice region 31. a semiconductor light emitting structure or active region 42, an electron blocking layer 51 (EBL), a p-side contact region 52, a current spreading electrode 60, a first electrode 70, and a second electrode 80.

The growth substrate 10 may be a sapphire substrate, a Si 111 substrate or the like. In particular, a patterned C-face sapphire substrate (C-face PSS) may be used, and there is no particular limitation on the use of heterogeneous or homogeneous substrates.

The buffer region 20 may be made of un-doped GaN that is formed on the seed layer, and its growth conditions (based on MOVCD method) are as follows: a temperature of 950° C. to 1100° C., a thickness of 1 to 4 μm, a pressure of 100 to 400 mbar, and H₂ atmosphere.

The n-side contact region 30 may be made of Si-doped GaN, and its growth conditions are as follows: a temperature of 1000° C. to 1100° C., a thickness of 1 to 4 μm, a pressure of 100 to 400 mbar, and H₂ atmosphere.

The superlattice region 31 is a stack of InₐGa₁₋ₐN/In_{b}Ga_{1-b}N (15 cycles of repetition of 0<a<1, 0≤b<1, a>b) superlattice structure that is formed under general growth conditions to improve current spreading. Optionally, Al can be added, and it can be doped with an n-type dopant (e.g., Si). Further, the composition may be slightly changed during the repetition process.

The electron blocking layer 51 may be made of Mg-doped AlGaN, and its growth conditions are as follows: a temperature of 900° C., a thickness of 10 to 40 nm, a pressure of 50 to 100 mbar, and H₂ atmosphere.

The p-side contact region 52 can also be made of Mg-doped GaN under general growth conditions.

The current spreading electrode 60 may be made of TCO (Transparent Conductive Oxide) such as ITO, but it is not limited thereto.

The first electrode 70 and the second electrode 80 may be made of Cr/Ni/Au.

The structure used in the example shown in FIG. 2 is a very common structure conventionally used to make semiconductor light emitting devices that emit blue and green light using Group III nitride semiconductors. Any structure suitable for Group III nitride semiconductor light emitting devices that emit blue and green light can be used without any specific limitations. While the presented form here is a lateral chip form, flip chip and vertical chip forms can also be used.

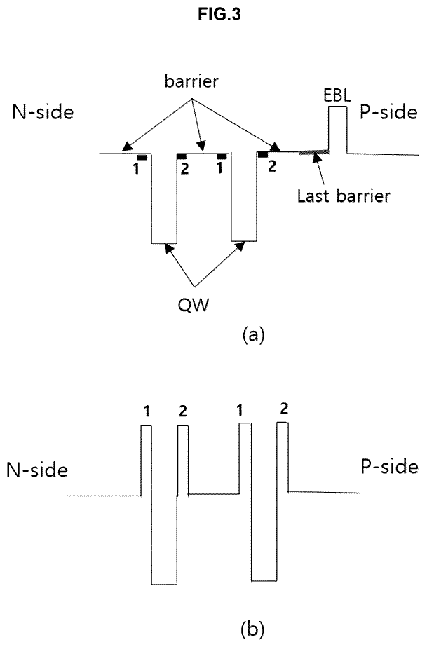

FIG. 3 shows examples of a semiconductor light emitting structure according to the present disclosure. FIG. 3A shows a conventional Group III nitride semiconductor light emitting structure that emits light in a green range, and FIG. 3B shows a Group III nitride semiconductor light emitting structure according to the present disclosure. For illustration purposes, two quantum wells are presented.

The semiconductor light emitting structure shown in FIG. 3A employs a quantum well (QW) made of In_{c}Ga_{1-c}N and a barrier made of Al_{d}GaₑIn_{1-d-e}N (0≤d≤1, 0≤e≤1; e.g. GaN). The content c of In significantly varies depending on the peak wavelength at which the semiconductor light emitting structure emits light. For example, in case of blue light emission, c can have a value of 0.1, while in case of green light emission, c can have a value of 0.2. Examples of the barrier may include InGaN, AlGaN, AlGaInN, and the like, but GaN is typically used.

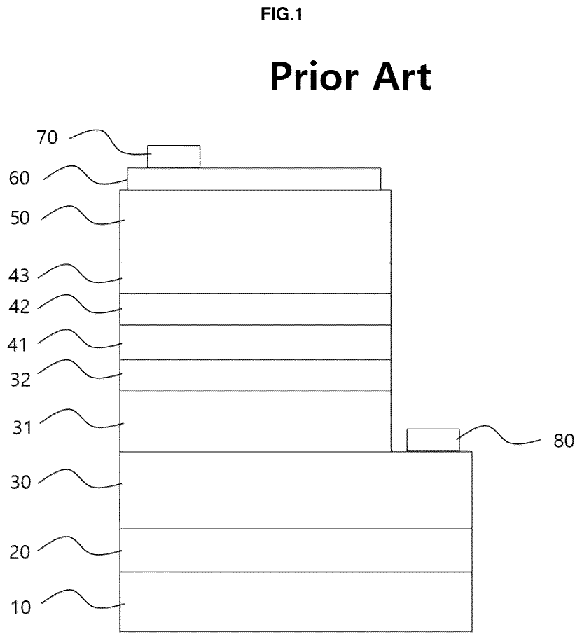

The semiconductor light emitting structure according to the present disclosure is a combination of the semiconductor light emitting structure as shown in FIG. 3A, which has already been commercially available and stably implemented, with the barrier structure as shown in FIG. 3B, such that light of longer wavelengths can be emitted. Incorporating the semiconductor light emitting structure of the present disclosure enables to overcome the issues in the In-rich InGaN active region of FIG. 1, as well as the issues in the operation of the semiconductor light emitting device thus manufactured.

TABLE 1

| | First (x), | First (x), | First (o), | First (o), |
|---|---|---|---|---|
| | Second (x) | Second (o) | Second (x) | Second (o) |
| Wavelength | 530 (Green) | 560 | 580 | 625 (Red) |
| (Wp, nm) | | | | |
| Optical power | Bright | Dim | Moderate | Moderate |
| (Qualitative | | | | |
| evaluation) | | | | |

As described in Table 1, (i) when neither first layer 1 nor the second layer 2 according to the present disclosure is not provided on either side of the quantum well, the device emits bright light at a wavelength of 530 nm, (ii) when only the second layer 2 according to the present disclosure is provided in the quantum well, the device emits dim light at a wavelength of 560 nm, (iii) when only the first layer 1 according to the present disclosure is provided in the quantum well, the device emits light of moderate brightness at a wavelength of 580 nm, and (iv) when both the first layer 1 and the second layer 2 according to the present disclosure are provided on both sides of the quantum well, the device emits light of moderate brightness at a wavelength of 625 nm.

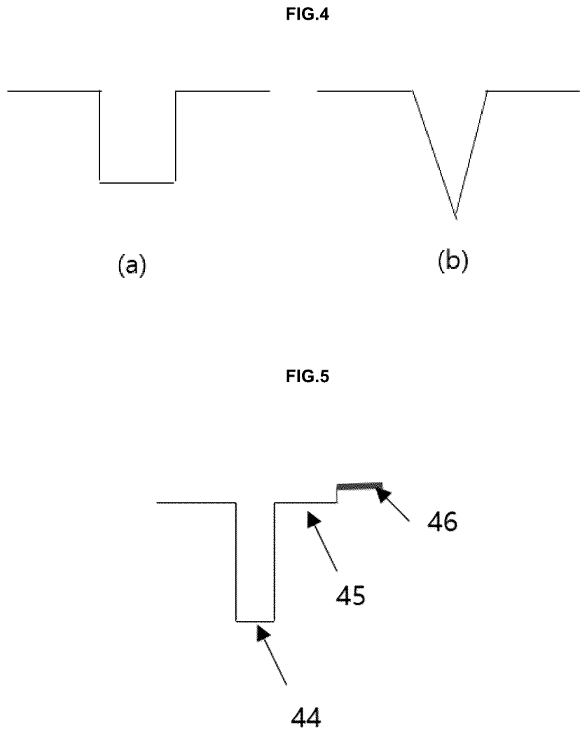

FIG. 4 shows other examples of a semiconductor light emitting structure according to the present disclosure. FIG. 4A shows an example in which In is uniformly distributed during the formation of a quantum well. FIG. 4B shows an example in which the distribution of In is graded (it is first decreased and then increased) during the formation of the quantum well. When the same total amount of In was provided to each quantum well, the structure in FIG. 4B exhibited brighter light.

FIG. 5 shows another example of a semiconductor light emitting structure according to the present disclosure. It demonstrates that changing the material composition of the last barrier (the barrier closest to the p-side in the semiconductor light emitting structure) from GaN to another material (such as InGaN) having a lower bandgap energy than GaN can extend the emission wavelength of the semiconductor light emitting structure. For example, it was confirmed that if an In/(In+Ga) ratio is appropriately adjusted (e.g., 0.05 or 0.10; where the ratio indicates the molar ratio between MO sources (TEGa (TriEthyl Ga), TMIn (TriMethyl In), TMAl (TriMethyl Al) in the vapor phase during growth), a semiconductor light emitting structure that emits light at a wavelength of 625 nm is capable of emitting light at a wavelength of 635 nm.

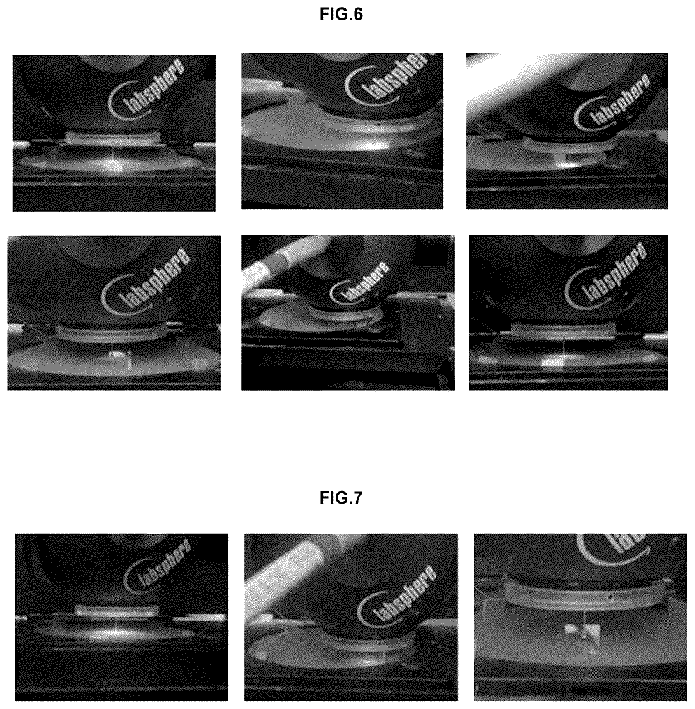

FIG. 6 shows an example of experimental results in the present disclosure. The top left illustrates a case where both the first layer 1 and the second layer 2 are absent (green); the top middle illustrates a case where only the second layer 2 is present (yellow); the top right illustrates a case where only the first layer 1 is present (orange); the bottom left illustrates a case where both the first layer 1 and the second layer 2 are present (red); the bottom middle illustrates a case in FIG. 5 (redder or more intense red); and the bottom right illustrates a case where Al_{f}Ga_{1-f}N (the ratio of Al/(Al+Ga) is 0.95) is used (blue).

For the experiments, a GaN barrier (4 nm) and an In_{c}Ga_{1-c}N well layer (2.5 nm) with an In/(In+Ga) ratio of 0.56 were used. In particular, two quantum wells were used to form a base structure as follows: GaN barrier (4 nm)-In_{c}Ga_{1-c}N well layer (2.5 nm)-GaN barrier (4 nm)-In_{c}Ga_{1-c}N well layer (2.5 nm)-GaN barrier (8 nm). Due to limitations in the experiments, 1 to 4 quantum wells were tested, but there were no significant changes in the optical properties. For the first layer 1 and the second layer 2, Al_{f}Ga_{1-f}N (2 nm) with an Al/(Al+Ga) ratio of 0.85 was used.

The well layers (quantum wells) were grown to a thickness of 2.5 nm at a temperature of 670° C. using TMGa and TMIn, and the barriers were grown to a thickness of 4 nm at a temperature of 770° C. using GaN. For the first layer 1 located first on the n-side, Al_{f}Ga_{1-f}N (2 nm) with an Al/(Al+Ga) ratio of 0.85 is grown using TMAl and TMGa under the same conditions as the first barrier immediately after the growth of the first barrier (located first on the n-side) (they together form the barrier). Immediately after the growth of the first quantum well (the first well layer located on the n-side), the second layer 2 located on the n-side is grown to a thickness of 0.3 nm using TMGa and TMAl by raising the temperature for 50 seconds. Afterwards, the remaining 1.7 nm is grown under the same growth conditions as the barrier, and the GaN barrier is grown. The first layer 1 and the second layer 2 located on the p-side are also grown in the same manner. The semiconductor light emitting structure 42 provided with the first layer 1 as well as the second layer 2 has the structure of the last GaN (1.5 nm) in the superlattice region 31-GaN barrier (4 nm)-first Al_{f}Ga_{1-f}N (2 nm) layer 1-In_{c}Ga_{1-c}N well layer (2.5 nm)-second Al_{f}Ga_{1-f}N (2 nm) layer 2-GaN barrier (4 nm)-first Al_{f}Ga_{1-f}N (2 nm) layer 1-In_{c}Ga_{1-c}N well layer (2.5 nm)-second Al_{f}Ga_{1-f}N (2 nm) layer (2)-GaN barrier (8 nm)-electron blocking layer (51). In the semiconductor light emitting structure shown in FIG. 5, the last barrier (adjacent to the electron blocking layer 51) can have the structure of In_{g}Ga_{1-g}N barrier (4 nm)-GaN barrier (4 nm).

As shown in FIG. 6, the emission wavelength can be shifted to the longer side by introducing the first layer 1 and/or the second layer 2 into a given semiconductor light emitting structure. However, as shown in the bottom right of FIG. 6, it is observed when the Al concentration in the first and second layers 1 and 2 is beyond a certain threshold, the wavelength shifts to a shorter range compared to the original emission wavelength of the semiconductor light emitting structure.

Table 2 below summarizes examples of growth conditions for conventional superlattice regions 31. As described earlier, the composition in the present disclosure is represented by the molar ratio between MO sources (TriEthyl Ga (TEGa), TriMethyl In (TMIn), and TriMethyl Al (TMAl).

TABLE 2

| | Growth | | |
|---|---|---|---|
| | temperature | Composition | Thickness |
| InₐGa₁₋ₐN | 720° C. | In/(In + Ga) = | 1.5 nm |
| (Superlattice region (31)) | | 0.55 | |
| In_{b}Ga_{1-b}N | 780° C. | b = 0 (GaN) | 1.5 nm |
| (Superlattice region (31)) | | | |

Here, the superlattice region 31 may be fully or partially doped. For example, only the barrier In_{b}Ga_{1-b}N (superlattice region 31) may be doped with Si at about 5×10¹⁸/cm³, or only the even-numbered barriers may be doped, or only the odd-numbered barriers may be doped.

Table 3 below summarizes examples of growth conditions for the conventional semiconductor light emitting structure or active region 42.

TABLE 3

| | Growth | | |
|---|---|---|---|
| | temperature | Composition | Thickness |
| Al_{d}GaₑIn_{1-d-e}N barrier | 770° C. | d = 0, e = 1 | 4 nm |
| (Semiconductor light emitting | | (GaN) | |
| structure (42)) | | | |
| In_{c}Ga_{1-c}N well layer | 670° C. | In/(In + Ga) = | 2.5 nm |
| (Semiconductor light emitting | | 0.56 | |
| structure (42)) | | | |
| Al_{d}GaₑIn_{1-d-e}N barrier | 770° C. | d = 0, e = 1 | 4 nm |
| (Semiconductor light emitting | | (GaN) | |
| structure (42)) | | | |
| In_{c}Ga_{1-c}N well layer | 670° C. | In/(In + Ga) = | 2.5 nm |
| (Semiconductor light emitting | | 0.56 | |
| structure (42)) | | | |
| Al_{d}GaₑIn_{1-d-e}N barrier | 770° C. | d = 0, e = 1 | 8 nm |
| (Semiconductor light emitting | | (GaN) | |
| structure (42)) | | | |

Table 4 below summarizes examples of growth conditions used for the semiconductor light emitting structure or active region 42 according to the present disclosure.

TABLE 4

| | Growth | | |
|---|---|---|---|
| | temperature | Composition | Thickness |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 8 nm |
| (Semiconductor light emitting | | (GaN) | |
| structure (42)) | | | |

Table 5 below summarizes examples of growth conditions used for the semiconductor light emitting structure or active region 42, as shown in FIG. 5.

TABLE 5

| | Growth | | |
|---|---|---|---|
| | temperature | Composition | Thickness |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| In_{g}Ga_{1-g}N well layer | 770° C. | In/(In + Ga) = | 4 nm |
| (Semiconductor light emitting | | 0.01 | |
| structure (42)) | | | |
| Al_{d}GaₑIn_{1-d-e}N barrier | 770° C. | d = 0, e = 1 | 4 nm |
| (Semiconductor light emitting | | (GaN) | |
| structure (42)) | | | |

FIG. 7 shows another example of experimental results in the present disclosure, related to changes in the emission wavelength based on the Al content in the semiconductor light emitting structure. The left illustrates a case where if the ratio of Al/(Al+Ga) is 0.25, yellow emission occurs; the middle illustrates a case where if the ratio of Al/(Al+Ga) is 0.75, red emission occurs; and the right illustrates a case where if the ratio of Al/(Al+Ga) is 0.95, blue emission occurs. With the semiconductor light emitting structure used in the experiment of FIG. 6, significant changes in the wavelength occurs when the Al content exceeds 20%, but the wavelength shorten again when the Al content exceeds 90%.

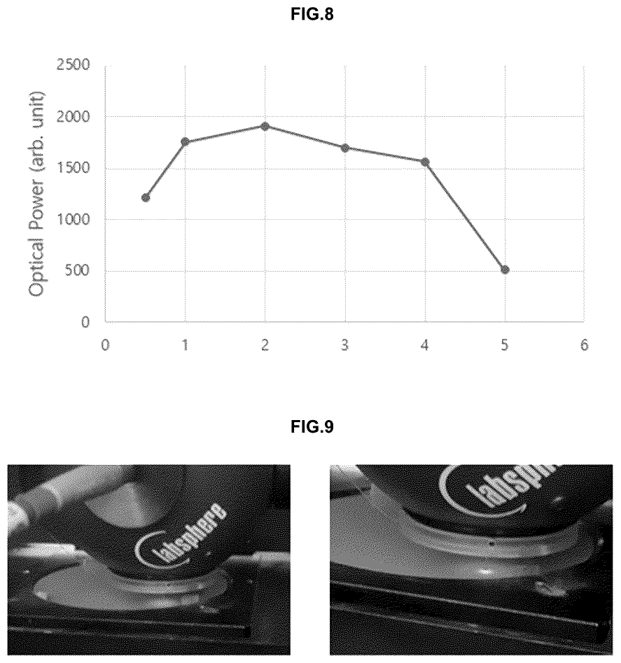

FIG. 8 shows another example of experimental results in the present disclosure, related to variations in optical power based on a change in the thickness of the first layer 1 and the second layer 2. With the semiconductor light emitting structure shown in FIG. 6, the maximum intensity is observed at approximately 2 nm, but it sharply drops as the thickness reaches 5 nm. A desirable range for the thickness is therefore 0.5-4 nm.

FIG. 9 shows another example of experimental results in the present disclosure, comparing the results of using the semiconductor light emitting structure in FIG. 4A (on the left) with the results of using the semiconductor light emitting structure in FIG. 4B (on the right). As can be seen, the example on the right shows brighter and more intense red emission.

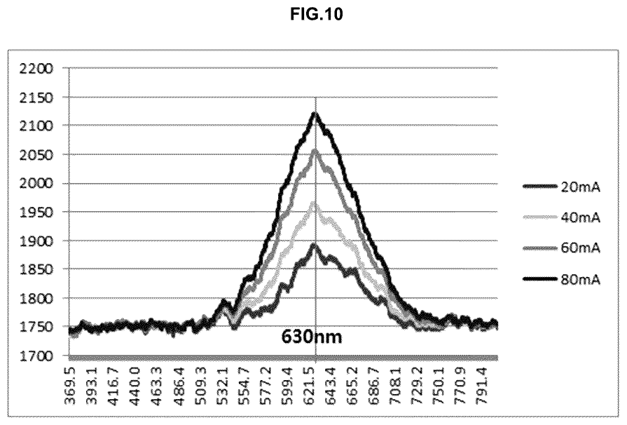

FIG. 10 shows another example of experimental results in the present disclosure, related to the degree of wavelength shift with changes in current. As compared with the conventional In-rich InGaN red LED (which shows a drastic shift towards shorter wavelengths with increased current), the wavelength shift is much less pronounced in this example.

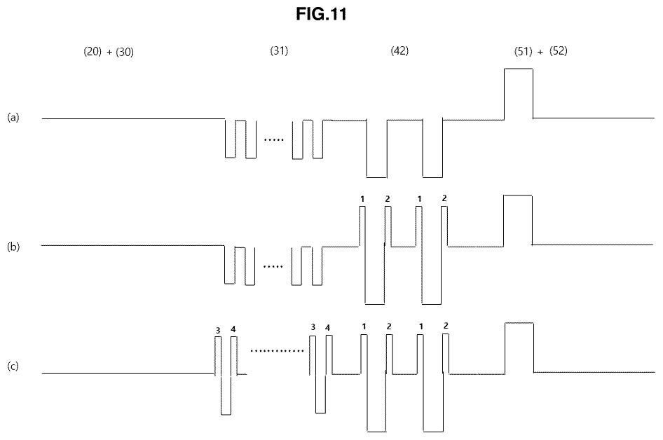

FIG. 11 illustrates bandgap energy of different semiconductor light emitting devices. FIG. 11A is obtained from a conventional semiconductor light emitting device, FIG. 11B is obtained from the semiconductor light emitting device shown in FIG. 2, and FIG. 11C is obtained from a semiconductor light emitting device which incorporates the barrier form of the semiconductor light emitting structure 42 into the superlattice region 31 in the structure shown in FIG. 11B.

Table 6 below summarizes examples of growth conditions used for the semiconductor light emitting device shown in FIG. 11C.

TABLE 6

| | Growth | | |
|---|---|---|---|
| | temperature | Composition | Thickness |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| : | : | : | : |
| <<15 cycles>> | | | |
| : | : | : | : |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 8 nm |
| (Semiconductor light emitting | | (GaN) | |
| structure (42)) | | | |

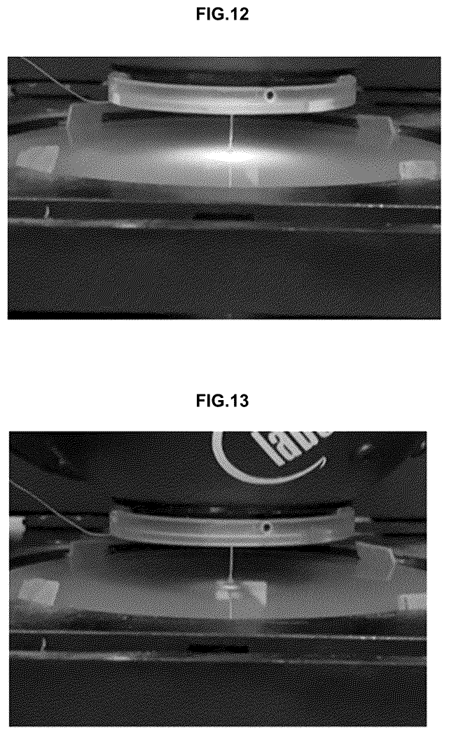

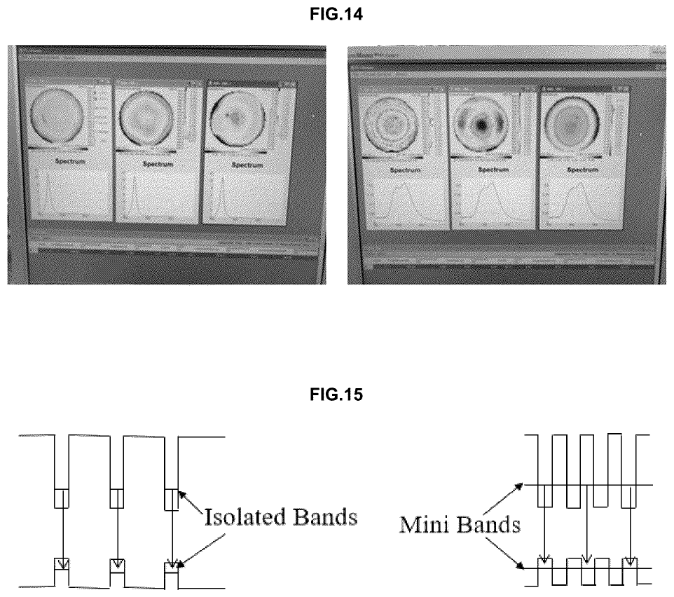

FIGS. 12 to 14 show further examples of experimental results in the present disclosure. In particular, FIG. 12 shows experimental results for the semiconductor light emitting device of FIG. 11C, for which all growth conditions are kept the same as in FIG. 11B except that the quantum well region 31 is absent. Similar to the example on the right side in FIG. 7, a shift towards shorter wavelengths is observed. This suggests that the incorporation of the third and fourth layers 3 and 4, into the superlattice region 31 (i.e. the superlattice region 31 as shown in FIG. 11C) increases the amount of In injected into the well layers of the semiconductor light emitting structure 42. FIG. 13 shows that when the ratio of Al/(Al+Ga) in the first and second layers 1 and 2 is lowered from 0.85 to 0.45, red light emission (635 nm) is at least twice as that of the semiconductor light emitting device of FIG. 11B. FIG. 14 shows PL measurement results of the superlattice region 31 with or without the third and fourth layers 3 and 4. The results confirm that in the presence of the third and fourth layers 3 and 4, the PL peak makes a significant shift in longer wavelength ranges, from 445 nm to 535 nm.

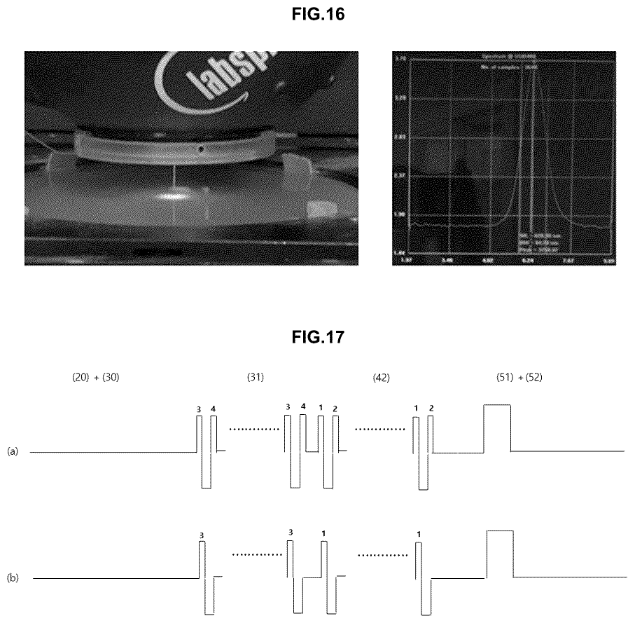

Table 7 below summarizes examples of growth conditions for the semiconductor light emitting device of FIG. 11C, in which the active region 42 of the quantum well structure is modified to a semiconductor light emitting region or active region 42 of the superlattice structure similar to the superlattice region 31. Referring to FIG. 15 which compares the active region of the quantum well structure (the left) with the active region of the superlattice structure (the right), each quantum well in the active region of the quantum well structure forms isolated bands due to a thick barrier and emits light independently through electron-hole recombination, while each well in the active region of the superlattice structure (that is, the barrier becomes sufficiently thin) is not isolated and forms mini-bands to emit light through miniband transition. Although the active region of the superlattice structure is not commonly used in Group III nitride semiconductor light emitting devices, it was found to be very effective when applied to the semiconductor light emitting structure of the present disclosure (see FIG. 16). That is to say, the active region 42 is constructed to be the same as the superlattice region 31, with some specific conditions as follows: 8 cycles are used; no doping is performed; the growth temperature for the well layers is set at 700° C., while the growth temperature for the other layers is set at 780° C., the thickness of the first and second layers 1 and 2 is set to 0.8 nm; the thickness of Al_{d}GaₑIn_{1-d-e}N barrier (d=0, e=1 (GaN)) is set to 1.5 nm; the ratio of the well layer In/(In+Ga) is set to 0.55; the ratio of Al/(Al+Ga) in the first layer 1 and the second layer 2 is set to 0.50; and the thickness of the well layer is set to 1.5 nm.

TABLE 7

| | Growth | | |
|---|---|---|---|
| | temperature | Composition | Thickness |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| InₐGa_{1-b}N well layer | 780° C. | b = 0 (GaN) | 1.5 nm |
| (Superlattice region (31)) | | | |
| : | : | : | : |
| <<15 cycles>> | | | |
| : | : | : | : |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| Al_{d}GaₑIn_{1-d-e}N barrier | 780° C. | d = 0, e = 1 | 4 nm |
| (Semiconductor light emitting | | (GaN) | |
| structure (42)) | | | |
| First Al_{f}Ga_{1-f}N layer (1) | 780° C. | Al/(Al + Ga) = | 0.8 nm |
| | | 0.50 | |
| In_{c}Ga_{1-c}N well layer | 700° C. | In/(In + Ga) = | 1.5 nm |
| (Semiconductor light emitting | | 0.55 | |
| structure (42)) | | | |
| Second Al_{f}Ga_{1-f}N layer (2) | 780° C. | Al/(Al + Ga) = | 0.8 nm |
| | | 0.50 | |
| Al_{d}GaₑIn_{1-d-e}N barrier | 780° C. | d = 0, e = 1 | 1.5 nm |
| (Semiconductor light emitting | | (GaN) | |
| structure (42)) | | | |
| : | : | : | : |
| <<8 cycles>> | | | |
| : | : | : | : |
| First Al_{f}Ga_{1-f}N layer (1) | 780° C. | Al/(Al + Ga) = | 0.8 nm |
| | | 0.50 | |
| In_{c}Ga_{1-c}N well layer | 700° C. | In/(In + Ga) = | 1.5 nm |
| (Semiconductor light emitting | | 0.55 | |
| structure (42)) | | | |
| Second Al_{f}Ga_{1-f}N layer (2) | 780° C. | Al/(Al + Ga) = | 0.8 nm |
| | | 0.50 | |
| Al_{d}GaₑIn_{1-d-e}N barrier | 780° C. | d = 0, e = 1 | 8 nm |
| (Semiconductor light emitting | | (GaN) | |
| structure (42)) | | | |

FIG. 16 shows an example of experimental results for the semiconductor light emitting structure described in Table 7. It confirms a 7-fold increase in output compared with the example described in Table 6.

FIG. 17 illustrates various examples of semiconductor light emitting structures employing a superlattice structure. In particular, FIG. 17A illustrates the bandgap energy of the semiconductor light emitting device described in Table 7, and FIG. 17B illustrates the semiconductor light emitting device from which the layers (i.e. the second layer 2 and the fourth layer 4) are removed from the p-side of the semiconductor light emitting structure 42 and the superlattice region 31. The semiconductor light emitting device illustrated in FIG. 17B demonstrated similar experimental results to those of the semiconductor light emitting device illustrated in FIG. 17A, under the same growth conditions but a modified ratio of Al/(Al+Ga) in the first layer 1 from 0.50 to 0.65.

In the semiconductor light emitting device illustrated in FIG. 17B, if the thickness of Al_{d}GaₑIn_{1-d-e}N barrier (d=0, e=1 (GaN)) of the semiconductor light emitting structure 42 is reduced from 1.5 nm to 1 nm, an emission wavelength shifts from 630 nm to 640 nm, moving toward a longer wavelength.

In the semiconductor light emitting device illustrated in FIG. 17B, if the repetition cycle of the semiconductor light emitting structure 42 is modified from 8 cycles to 16 cycles, an emission wavelength shortens to 625 nm, while the power intensity remains relatively similar.

In the semiconductor light emitting device illustrated in FIG. 17B, if the thickness of Al_{d}GaₑIn_{1-d-e}N barrier (d=0, e=1 (GaN)) of the semiconductor light emitting structure 42 is reduced from 1.5 nm to 0.75 nm, the thickness of the first layer 1 is reduced from 0.8 nm to 0.4 nm, and the thickness of the well layer is reduced from 1.5 nm to 0.75 nm, the wavelength shortens from 630 nm to 600 nm and the optical power is lowered by at least 50%.

In the semiconductor light emitting device illustrated in FIG. 17B, if the thickness of Al_{d}GaₑIn_{1-d-e}N barrier (d=0, e=1 (GaN)) of the semiconductor light emitting structure 42 is reduced from 1.5 nm to 1.0 nm, the thickness of the first layer 1 is remained at 0.8 nm, and the thickness of the well layer is increased from 1.5 nm to 2.0 nm, the wavelength significantly increases from 630 nm to 680 nm, while the optical power is lowered by at least 50%. With these conditions, raising the growth temperature to a higher level may change the emission wavelength back to 630 nm, while the optical power is increased by 20% as compared with the semiconductor light emitting device illustrated in FIG. 17B.

Various changes can be made, which may include adding dopants to each layer of the superlattice region 31 and the semiconductor light emitting structure 42, adding Al, In or Ga, or slightly modifying the composition and growth conditions during the repetition process.

Various exemplary embodiments of the present disclosure are described below:

(1) A method for manufacturing a Group III nitride semiconductor light emitting structure that emits red light having an emission peak wavelength of at least 600 nm, the method comprising: growing a first superlattice region formed of alternating stacked first sub-layers and second sub-layers; and growing an active region on the first superlattice region, with the active region including a third sub-layer made of an Al-containing Group III nitride semiconductor and having a first bandgap energy, a fourth sub-layer made of an In-containing Group III nitride semiconductor and having a second bandgap energy smaller than the first bandgap energy and a fifth sub-layer made of an Al-containing Group III nitride semiconductor and having a third bandgap energy smaller than the second bandgap energy, wherein if the third sub-layer and the fifth sub-layer is based on GaN, the In content in the fourth sub-layer is set such that the fourth sub-layer emits light having a peak emission wavelength of 600 nm or less, and the Al content in the third sub-layer and the Al content in the fifth sub-layer are set such that the fourth sub-layer emits red light having a peak emission wavelength of at least 600 nm.

(2) The method for manufacturing a Group III nitride semiconductor light emitting structure of embodiment (1), wherein the active region comprises a quantum well structure, the fourth sub-layer is a quantum well layer, and the third and fifth sub-layers are quantum barriers (see FIG. 3).

(3) The method for manufacturing a Group III nitride semiconductor light emitting structure of embodiment (2), wherein, during the growth of the fourth sub-layer, the supply of In is first decreased and then increased (see FIG. 4).

(4) The method for manufacturing a Group III nitride semiconductor light emitting structure of embodiment (2), wherein growing an active region comprises sequentially growing the third sub-layer, the fourth sub-layer and the fifth sub-layer multiple times, and the fifth sub-layer provided on the uppermost side contains InGaN such that a peak emission wavelength of the entire active region shifts towards longer wavelengths (see FIG. 5).

(5) The method for manufacturing a Group III nitride semiconductor light emitting structure of embodiment (4), wherein the fifth sub-layer provided on the uppermost side is made of InGaN—GaN.

(6) The method for manufacturing a Group III nitride semiconductor light emitting structure of embodiment (2), wherein the third sub-layer and the fifth sub-layer are each made of AlGaN—GaN—AlGaN.

(7) The method for manufacturing a Group III nitride semiconductor light emitting structure of embodiment (1), wherein the first sub-layer has a fourth band gap energy, the second sub-layer has a fifth band gap energy greater than the fourth band gap energy, and the second sub-layer is made of AlGaN—(In)GaN, AlGaN—(In)GaN—AlGaN or (In)GaN—AlGaN (see FIG. 11C).

(8) The method for manufacturing a Group III nitride semiconductor light emitting structure of embodiment (7), wherein the Al content of AlGaN in the second sub-layer is smaller than the Al content in the third sub-layer and the Al content in the fifth sub-layer.

(9) The method for manufacturing a Group III nitride semiconductor light emitting structure of embodiment (1), wherein the active region comprises a superlattice structure (see Table 7).

(10) The method for manufacturing a Group III nitride semiconductor light emitting structure of embodiment (9), wherein the third sub-layer and the fifth sub-layer are made of GaN—AlGaN (see FIG. 17B).

The words such as “particular,” “specific,” “certain,” and “given,” in the description and claims, if used, are to distinguish or identify, and are not intended to be otherwise limiting.

As used herein, including in the claims, singular forms of terms are to be construed as also including the plural form and vice versa, unless the context indicates otherwise. Thus, it should be noted that as used herein, the singular forms “a,” “an,” and “the” include plural references unless the context clearly dictates otherwise.

It will be appreciated that variations to the embodiments of the invention can be made while still falling within the scope of the invention. Alternative features serving the same, equivalent or similar purpose can replace features disclosed in the specification, unless stated otherwise. Thus, unless stated otherwise, each feature disclosed represents one example of a generic series of equivalent or similar features.

While the invention has been described in connection with what is presently considered to be the most practical and preferred embodiments, it is to be understood that the invention is not to be limited to the disclosed embodiment, but on the contrary, is intended to cover various modifications and equivalent arrangements included within the spirit and scope of the appended claims.

What is claimed is:

1. A method for manufacturing a Group III nitride semiconductor light emitting structure that emits red light having an emission peak wavelength of at least 600 nm, the method comprising:
growing a first superlattice region formed of alternating stacked first sub-layers and second sub-layers; and
growing an active region on the first superlattice region, the active region including a third sub-layer made of an Al-containing Group III nitride semiconductor and having a first bandgap energy, a fourth sub-layer made of an In-containing Group III nitride semiconductor and having a second bandgap energy smaller than the first bandgap energy and a fifth sub-layer made of an Al-containing Group III nitride semiconductor and having a third bandgap energy smaller than the second bandgap energy,
wherein if the third sub-layer and the fifth sub-layer is based on GaN, the In content in the fourth sub-layer is set such that the fourth sub-layer emits light having a peak emission wavelength of 600 nm or less, and
the Al content in the third sub-layer and the Al content in the fifth sub-layer are set such that the fourth sub-layer emits red light having a peak emission wavelength of at least 600 nm.

2. The method for manufacturing a Group III nitride semiconductor light emitting structure of claim 1, wherein the active region comprises a quantum well structure, the fourth sub-layer is a quantum well layer, and the third and fifth sub-layers are quantum barriers.

3. The method for manufacturing a Group III nitride semiconductor light emitting structure of claim 2, wherein, during the growth of the fourth sub-layer, the supply of In is first decreased and then increased.

4. The method for manufacturing a Group III nitride semiconductor light emitting structure of claim 2, wherein growing an active region comprises sequentially growing the third sub-layer, the fourth sub-layer and the fifth sub-layer multiple times, and
the fifth sub-layer provided on the uppermost side contains InGaN such that a peak emission wavelength of the entire active region shifts towards longer wavelengths.

5. The method for manufacturing a Group III nitride semiconductor light emitting structure of claim 4, wherein the fifth sub-layer provided on the uppermost side is made of InGaN—GaN.

6. The method for manufacturing a Group III nitride semiconductor light emitting structure of claim 2, wherein the third sub-layer and the fifth sub-layer are each made of AlGaN—GaN—AlGaN.

7. The method for manufacturing a Group III nitride semiconductor light emitting structure of claim 1, wherein the first sub-layer has a fourth band gap energy,
the second sub-layer has a fifth band gap energy greater than the fourth band gap energy, and
the second sub-layer is made of AlGaN—(In)GaN, AlGaN—(In)GaN—AlGaN or (In)GaN—AlGaN.

8. The method for manufacturing a Group III nitride semiconductor light emitting structure of claim 7, wherein the Al content of AlGaN in the second sub-layer is smaller than the Al content in the third sub-layer and the Al content in the fifth sub-layer.

9. The method for manufacturing a Group III nitride semiconductor light emitting structure of claim 1, wherein the active region comprises a superlattice structure.

10. The method for manufacturing a Group III nitride semiconductor light emitting structure of claim 9, wherein the third sub-layer and the fifth sub-layer are made of GaN—AlGaN.
